(19) United States
(12) Patent Application Publication
(10) Pub. No.: US 2026/0095150 A1
(43) Pub. Date: Apr. 2, 2026

(54) ACOUSTIC WAVE FILTER AND MULTIPLEXER

(71) Applicant: Murata Manufacturing Co., Ltd., Nagaokakyo-shi (JP)

(72) Inventor: Naoki OSHIMA, Nagaokakyo-shi (JP)

(21) Appl. No.: 19/341,498

(22) Filed: Sep. 26, 2025

(30) Foreign Application Priority Data
Oct. 1, 2024 (JP) 2024-171932

(51) Int. Cl. H03H 9/64; H03H 9/02; H03H 9/72

(52) U.S. Cl. CPC H03H 9/6433; H03H 9/02992; H03H 9/725

(57) ABSTRACT

An acoustic wave filter includes a longitudinally coupled resonator acoustic wave filter including n IDT electrodes, and first and second reference-potential wiring lines each connected to a reference potential. The longitudinally coupled resonator acoustic wave filter includes first and second areas. The first area includes a first-end-positioned IDT electrode to a center-positioned IDT electrode in a direction in which the IDT electrodes are arranged side by side. The second area includes the center-positioned IDT electrode to a second-end-positioned IDT electrode in the direction in which the IDT electrodes are arranged side by side. Each of the IDT electrodes includes a first comb-shaped electrode and a second comb-shaped electrode interdigitated with each other. In each of the IDT electrodes, one of the first comb-shaped electrode and the second comb-shaped electrode is connected to the signal potential, and the other is connected to the reference potential.

### CROSS REFERENCE TO RELATED APPLICATIONS

This application claims the benefit of priority to Japanese Patent Application No. 2024-171932 filed on Oct. 1, 2024. The entire contents of this application are hereby incorporated herein by reference.

### BACKGROUND OF THE INVENTION

### 1. Field of the Invention

The present invention relates to acoustic wave filters and multiplexers.

### 2. Description of the Related Art

To date, acoustic wave filters have been used widely as filters in cellular phones. International Publication No. 2019/131533 discloses an example of an acoustic wave filter. The acoustic wave filter has a longitudinally coupled resonator unit. The longitudinally coupled resonator unit includes three or more interdigital transducer (IDT) electrodes. Each IDT electrode includes a pair of comb-shaped electrodes. One of the comb-shaped electrodes in each IDT electrode is connected to the signal potential, the other is connected to the ground potential. Comb-shaped electrodes of some of the IDT electrodes are connected to the ground potential through the same wiring line. Comb-shaped electrodes of the remaining IDT electrodes are connected to the ground potential through a wiring line different from the wiring line described above.

For example, the acoustic wave filter described in International Publication No. 2019/131533 is used along with other filter devices in a multiplexer such as a duplexer. However, the acoustic wave filter has a difficulty in making the out-of-band attenuation sufficiently high. Therefore, when the acoustic wave filter is used in a multiplexer, it is difficult to make the isolation characteristics sufficiently high.

### SUMMARY OF THE INVENTION

Example embodiments of the present invention provide acoustic wave filters each with a larger out-of-band attenuation, and multiplexers each with improved isolation characteristics.

An acoustic wave filter according to an example embodiment of the present invention includes a longitudinally coupled resonator acoustic wave filter including n IDT electrodes where n is an odd number of seven or more, and a first reference-potential wiring line and a second reference-potential wiring line each connected to a reference potential. The longitudinally coupled resonator acoustic wave filter includes a first area and a second area. The first area includes a first-end-positioned IDT electrode to a center-positioned IDT electrode in a direction in which the n IDT electrodes are arranged side by side. The second area includes the center-positioned IDT electrode to a second-end-positioned IDT electrode in the direction in which the n IDT electrodes are arranged side by side. Each of the IDT electrodes includes a first comb-shaped electrode and a second comb-shaped electrode interdigitated with each other. One of the first comb-shaped electrode and the second comb-shaped electrode in each IDT electrode is connected to a signal potential. An other of the first comb-shaped electrode and the second comb-shaped electrode is connected to the reference potential. A first one in each pair of adjacent IDT electrodes includes the first comb-shaped electrode connected to the signal potential. A second one in the pair includes the first comb-shaped electrode connected to the reference potential. In the first area, all of the first comb-shaped electrodes connected to the reference potential are connected to the first reference-potential wiring line, and the second comb-shaped electrodes connected to the reference potential include a second comb-shaped electrode connected to the first reference-potential wiring line and a second comb-shaped electrode connected to the second reference-potential wiring line. In the second area, the first comb-shaped electrodes connected to the reference potential include a first comb-shaped electrode connected to the first reference-potential wiring line and a first comb-shaped electrode connected to the second reference-potential wiring line, and all of the second comb-shaped electrodes connected to the reference potential are connected to the second reference-potential wiring line.

A multiplexer according to an example embodiment of the present invention includes multiple filter devices. At least one of the filter devices includes an acoustic wave filter according to an example embodiment of the present invention.

Acoustic wave filters according to example embodiments of the present invention each achieve a larger out-of-band attenuation. Multiplexers according to example embodiments of the present invention each achieve improved isolation characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a duplexer according to a first example embodiment of the present invention.

FIG. 2 is a schematic plan view of a longitudinally coupled resonator acoustic wave filter according to the first example embodiment of the present invention.

FIG. 3 is a schematic view of a longitudinally coupled resonator acoustic wave filter according to the first example embodiment of the present invention.

FIG. 4 is a schematic view of a longitudinally coupled resonator acoustic wave filter according to a first comparison example.

FIG. 5 is a schematic view of a longitudinally coupled resonator acoustic wave filter according to a second comparison example.

FIG. 6 is a diagram illustrating isolation characteristics of duplexers of the first example embodiment of the present invention, the first comparison example, and the second comparison example.

FIG. 7 is a diagram illustrating attenuation-frequency characteristics of transmit filters according to the first example embodiment of the present invention and the second comparison example.

FIG. 8 is a diagram illustrating attenuation-frequency characteristics of receive filters according to the first example embodiment of the present invention and the second comparison example.

FIG. 9 is an enlarged view of the vicinity of the passband of the transmit filters in FIG. 8.

FIG. 10 is a schematic view of a multiplexer according to a second example embodiment of the present invention.

### DETAILED DESCRIPTION OF THE EXAMPLE EMBODIMENTS

Referring to the drawings, example embodiments of the present invention will be described in detail.

Example embodiments of the present invention described in this specification are examples, and partial replacement or combination of configurations in different example embodiments may be made.

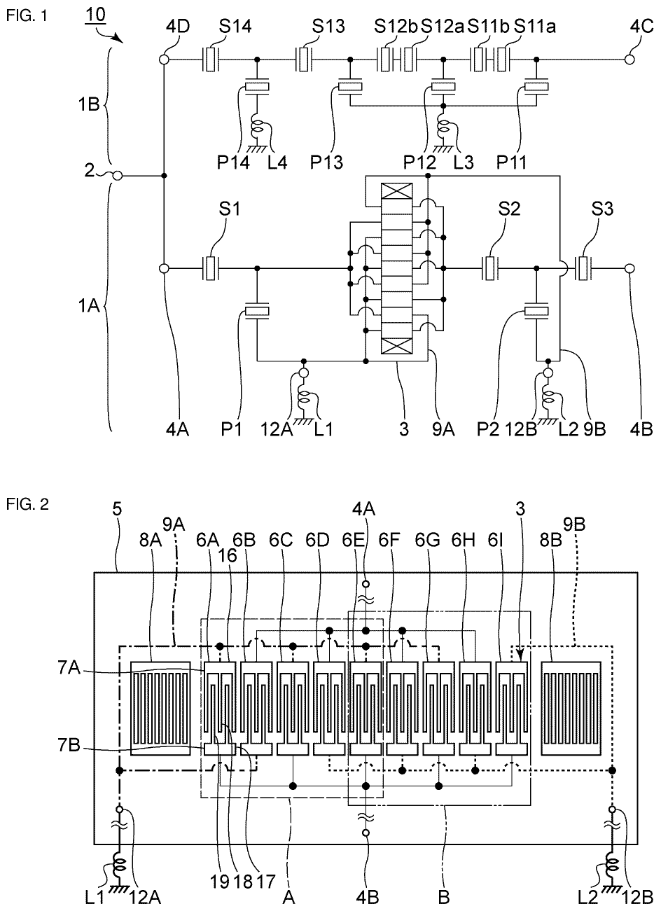

FIG. 1 is a circuit diagram of a duplexer according to a first example embodiment of the present invention.

A duplexer 10 is a multiplexer according to the first example embodiment of the present invention. Specifically, the duplexer 10 includes a receive filter 1A, a transmit filter 1B, and a common connection terminal 2. The receive filter 1A and the transmit filter 1B are commonly connected to the common connection terminal 2. The receive filter 1A is an acoustic wave filter according to an example embodiment of the present invention.

The multiplexer according to an example embodiment of the present invention is not limited to a duplexer. For example, the multiplexer may include three or more filter devices. Any configuration may be provided as long as at least one of the filter devices included in the multiplexer is an acoustic wave filter according to an example embodiment of the present invention.

In the specification, the passband of the multiplexer or the filter devices is a band defined by a standard for a communication band or the like. The communication band of the duplexer 10 is, for example, Band 28. Thus, the passband of the receive filter 1A is, for example, about 758 MHz to about 803 MHz which defines and functions as the receive band of Band 28. The passband of the transmit filter 1B is, for example, about 703 MHz to about 748 MHz which defines and functions as the transmit band of Band 28. The passbands of the receive filter 1A and the transmit filter 1B are not limited to those described above.

As illustrated in FIG. 1, the receive filter 1A includes a longitudinally coupled resonator acoustic wave filter 3, multiple acoustic wave resonators, a first signal terminal 4A, a second signal terminal 4B, a first reference-potential wiring line 9A and a second reference-potential wiring line 9B, a first reference-potential terminal 12A, and a second reference-potential terminal 12B. Specifically, the acoustic wave resonators include multiple serial arm resonators and multiple parallel arm resonators.

Each of the first reference-potential wiring line 9A and the second reference-potential wiring line 9B is a wiring line connected to the reference potential. Each of the first reference-potential terminal 12A and the second reference-potential terminal 12B is a terminal connected to the reference potential. The first reference-potential wiring line 9A is connected to the first reference-potential terminal 12A. Thus, the first reference-potential wiring line 9A is connected to the reference potential through the first reference-potential terminal 12A. The second reference-potential wiring line 9B is connected to the second reference-potential terminal 12B. Thus, the second reference-potential wiring line 9B is connected to the reference potential through the second reference-potential terminal 12B.

In contrast, the transmit filter 1B is, for example, a ladder filter. Specifically, the transmit filter 1B includes multiple serial arm resonators and multiple parallel arm resonators, a third signal terminal 4C, and a fourth signal terminal 4D. In the description below, the acoustic wave resonators, the serial arm resonators, the parallel arm resonators, and the longitudinally coupled resonator acoustic wave filter may be described collectively as resonators.

The first signal terminal 4A of the receive filter 1A and the fourth signal terminal 4D of the transmit filter 1B are connected to the common connection terminal 2. The common connection terminal 2 is, for example, an antenna terminal. The antenna terminal is connected to an antenna. The common connection terminal 2 is not necessarily an antenna terminal.

In the present example embodiment, the common connection terminal 2, the second signal terminal 4B, the third signal terminal 4C, the first reference-potential terminal 12A, and the second reference-potential terminal 12B are defined by electrode pads. In contrast, the first signal terminal 4A and the fourth signal terminal 4D are defined by wiring lines. Each of the terminals may be defined by an electrode pad or a wiring line.

In the receive filter 1A, the longitudinally coupled resonator acoustic wave filter 3 is connected between the first signal terminal 4A and the second signal terminal 4B. A specific configuration of the longitudinally coupled resonator acoustic wave filter 3 will be described below.

FIG. 2 is a schematic plan view of a longitudinally coupled resonator acoustic wave filter according to the first example embodiment. FIG. 2 illustrates the first reference-potential wiring line 9A by using a long dashed short dashed line, and illustrates the second reference-potential wiring line 9B by using a dashed line. FIG. 2 illustrates areas, described below, by using a dashed line and a long dashed double-short dashed line. The same is true for schematic views, described below, of the longitudinally coupled resonator acoustic wave filter.

The longitudinally coupled resonator acoustic wave filter 3 includes a piezoelectric substrate 5 and multiple interdigital transducer (IDT) electrodes. The duplexer 10 may include the piezoelectric substrate 5 including the longitudinally coupled resonator acoustic wave filter 3. The piezoelectric substrate 5 has piezoelectricity. The piezoelectric substrate 5 includes only piezoelectric material. The piezoelectric material may be, for example, lithium tantalate, lithium niobate, zinc oxide, aluminum nitride, crystal, or lead zirconate titanate (PZT). The piezoelectric substrate 5 may be a multilayer substrate including a piezoelectric layer.

In the present example embodiment, all of the resonators of the receive filter 1A and the transmit filter 1B in FIG. 1 share the piezoelectric substrate 5. The terminals in FIG. 1 are disposed on the piezoelectric substrate 5. More specifically, the common connection terminal 2, the first signal terminal 4A, the second signal terminal 4B, the third signal terminal 4C, the fourth signal terminal 4D, the first reference-potential terminal 12A, and the second reference-potential terminal 12B are disposed on the piezoelectric substrate 5. However, each resonator may include its own piezoelectric substrate 5. Multiple terminals may be provided on piezoelectric substrates 5 different from each other.

As illustrated in FIG. 2, the longitudinally coupled resonator acoustic wave filter 3 includes, for example, nine IDT electrodes. The nine IDT electrodes are disposed on the piezoelectric substrate 5. Specifically, the nine IDT electrodes of the longitudinally coupled resonator acoustic wave filter 3 include an IDT electrode 6A, an IDT electrode 6B, an IDT electrode 6C, an IDT electrode 6D, an IDT electrode 6E, an IDT electrode 6F, an IDT electrode 6G, an IDT electrode 6H, and an IDT electrode 6I. The longitudinally coupled resonator acoustic wave filter 3 has a one-stage configuration.

The number of IDT electrodes of the longitudinally coupled resonator acoustic wave filter 3 is not limited to nine. In example embodiments of the present invention, any configuration may be provided as long as the longitudinally coupled resonator acoustic wave filter 3 includes n IDT electrodes where n is an odd number of seven or more. More specifically, in example embodiments of the present invention, n is any odd number of seven or more, and, for example, n=9 in the first example embodiment. However, in example embodiments of the present invention, n may be an odd number, such as seven or eleven, for example.

The IDT electrode 6A of the longitudinally coupled resonator acoustic wave filter 3 includes a pair of comb-shaped electrodes. Specifically, the pair of comb-shaped electrodes include a first comb-shaped electrode 7A and a second comb-shaped electrode 7B. The first comb-shaped electrode 7A includes a first busbar 16 and multiple first electrode fingers 18. One end of each of the first electrode fingers 18 is connected to the first busbar 16. The second comb-shaped electrode 7B includes a second busbar 17 and multiple second electrode fingers 19. One end of each of the second electrode fingers 19 is connected to the second busbar 17.

The first comb-shaped electrode 7A and the second comb-shaped electrode 7B are arranged so that the first busbar 16 is opposite the second busbar 17. The first electrode fingers 18 and the second electrode fingers 19 are interdigitated with each other. Thus, the first comb-shaped electrode 7A and the second comb-shaped electrode 7B are interdigitated with each other.

In the description below, the first comb-shaped electrode 7A and the second comb-shaped electrode 7B may be collectively described simply as comb-shaped electrodes. The first electrode fingers 18 and the second electrode fingers 19 may be collectively described simply as electrode fingers. The direction in which the electrode fingers extend is referred to as the electrode-finger extension direction, the direction orthogonal or substantially orthogonal to the electrode-finger extension direction is referred to as the electrode-finger orthogonal direction. The first busbar 16 is positioned on one side in the electrode-finger extension direction, and the second busbar 17 is positioned on the other side.

Similar to the IDT electrode 6A, each of the IDT electrodes other than the IDT electrode 6A of the longitudinally coupled resonator acoustic wave filter 3 includes a pair of comb-shaped electrodes. The electrode-finger orthogonal direction of each IDT electrode of the longitudinally coupled resonator acoustic wave filter 3 is the same.

Application of an alternating voltage to each IDT electrode causes acoustic waves to be excited. The acoustic-wave propagation direction of each IDT electrode is parallel or substantially parallel to the electrode-finger orthogonal direction. The nine IDT electrodes of the longitudinally coupled resonator acoustic wave filter 3 are arranged side by side in the acoustic-wave propagation direction. Specifically, in the direction in which the nine IDT electrodes are arranged side by side, the IDT electrode 6A, the IDT electrode 6B, the IDT electrode 6C, the IDT electrode 6D, the IDT the electrode 6E, the IDT electrode 6F, the IDT electrode 6G, the IDT electrode 6H, and the IDT electrode 6I are arranged side by side in this order.

The longitudinally coupled resonator acoustic wave filter 3 includes a pair of reflectors. Specifically, the pair of reflectors include a reflector 8A and a reflector 8B. More specifically, the reflector 8A and the reflector 8B are arranged on the piezoelectric substrate 5 so as to be opposite each other with the nine IDT electrodes interposed in between in the acoustic-wave propagation direction. Each of the IDT electrodes and the reflectors may include a multilayer metal film or a single-layer metal film.

FIG. 3 is a schematic view of the longitudinally coupled resonator acoustic wave filter according to the first example embodiment. In FIG. 3, each of the IDT electrodes and the reflectors is illustrated as a rectangular schematic figure. In FIG. 3, each of the IDT electrodes is hatched. In FIG. 3, wiring lines connected to upper portions, in FIG. 3, of IDT electrodes indicate that the wiring lines are connected to the first comb-shaped electrodes of the IDT electrodes. In contrast, in FIG. 3, wiring lines connected to lower portions, in FIG. 3, of IDT electrodes indicate that the wiring lines are connected to the second comb-shaped electrodes of the IDT electrodes. The same is true in schematic views other than that in FIG. 3.

In the description below, the order in which the nine IDT electrodes are arranged side by side represents the numbers of the IDT electrodes, and the number of the IDT electrode 6A is one. The numbers of the IDT electrode 6A, the IDT electrode 6C, the IDT electrode 6E, the IDT electrode 6G, and the IDT electrode 6I are odd. In contrast, the numbers of the IDT electrode 6B, the IDT electrode 6D, the IDT electrode 6F, and the IDT electrode 6H are even.

In each IDT electrode, the first comb-shaped electrode or the second comb-shaped electrode is connected to the signal potential, and the other of the first comb-shaped electrode or the second comb-shaped electrode is connected to the reference potential. Specifically, in the first IDT electrode 6A, the first comb-shaped electrode is connected to the reference potential, and the second comb-shaped electrode is connected to the signal potential. In each of the other odd-numbered IDT electrodes, the first comb-shaped electrode is connected to the reference potential, and the second comb-shaped electrode is connected to the signal potential. More specifically, the second comb-shaped electrodes in the odd-numbered IDT electrode are connected to the signal potential on the second signal terminal 4B side.

In contrast, in each even-numbered IDT electrode, the first comb-shaped electrode is connected to the signal potential, and the second comb-shaped electrode is connected to the reference potential. More specifically, the first comb-shaped electrodes in the even-numbered IDT electrode are connected to the signal potential on the first signal terminal 4A side.

In the longitudinally coupled resonator acoustic wave filter 3, any of the odd-numbered IDT electrodes is adjacent to any of the even-numbered IDT electrodes. The first comb-shaped electrode of one of the adjacent IDT electrodes is connected to the signal potential, and the first comb-shaped electrode of the other of the adjacent IDT electrodes is connected to the reference potential.

On the piezoelectric substrate 5, the first reference-potential wiring line 9A, which is schematically illustrated by using a long dashed short dashed line, and the second reference-potential wiring line 9B, which is schematically illustrated by using a dashed line, are provided. The first reference-potential wiring line 9A and the second reference-potential wiring line 9B are connected to the reference potential. In the longitudinally coupled resonator acoustic wave filter 3, the comb-shaped electrodes connected to the reference potential are connected to the first reference-potential wiring line 9A or the second reference-potential wiring line 9B.

The first reference-potential wiring line 9A is not connected to the second reference-potential wiring line 9B. The first reference-potential terminal 12A is not connected to the second reference-potential terminal 12B. That is, in the receive filter 1A defining and functioning as an acoustic wave filter, the path on which the first reference-potential wiring line 9A is connected to the reference potential is different from the path on which the second reference-potential wiring line 9B is connected to the reference potential.

As illustrated in FIG. 3, the longitudinally coupled resonator acoustic wave filter 3 includes a first area A and a second area B. Specifically, the first area A is an area including the IDT electrode 6A, which is positioned at one end, to the IDT electrode 6E, which is positioned at the center, in the direction in which the nine IDT electrodes are arranged side by side. The second area B is an area including the IDT electrode 6E, which is positioned at the center, to the IDT electrode 6I, which is positioned on the other end, in the direction in which the nine IDT electrodes are arranged side by side.

In the first area A, the first comb-shaped electrodes connected to the reference potential are those of the IDT electrode 6A, the IDT electrode 6C, and the IDT electrode 6E. All of these first comb-shaped electrodes are connected to the first reference-potential wiring line 9A.

In the first area A, the second comb-shaped electrodes connected to the reference potential are those of the IDT electrode 6B and the IDT electrode 6D. The second comb-shaped electrode of the IDT electrode 6B is connected to the first reference-potential wiring line 9A. The second comb-shaped electrode of the IDT electrode 6D is connected to the second reference-potential wiring line 9B. Thus, the second comb-shaped electrodes connected to the reference potential include a second comb-shaped electrode connected to the first reference-potential wiring line 9A and a second comb-shaped electrode connected to the second reference-potential wiring line 9B.

In the second area B, the first comb-shaped electrodes connected to the reference potential are those of the IDT electrode 6E, the IDT electrode 6G, and the IDT electrode 6I. The first comb-shaped electrodes of the IDT electrode 6E and the IDT electrode 6G are connected to the first reference-potential wiring line 9A. The first comb-shaped electrode of the IDT electrode 6I is connected to the second reference-potential wiring line 9B. Thus, the first comb-shaped electrodes connected to the reference potential include a first comb-shaped electrode connected to the first reference-potential wiring line 9A and a first comb-shaped electrode connected to the second reference-potential wiring line 9B.

In the second area B, the second comb-shaped electrodes connected to the reference potential are those of the IDT electrode 6F and the IDT electrode 6H. All of these second comb-shaped electrodes are connected to the second reference-potential wiring line 9B.

The present example embodiment includes the following four configurations 1) to 4). 1) In the first area A, all of the first comb-shaped electrodes connected to the reference potential are connected to the first reference-potential wiring line 9A. 2) In the first area A, the second comb-shaped electrodes connected to the reference potential include a second comb-shaped electrode connected to the first reference-potential wiring line 9A and a second comb-shaped electrode connected to the second reference-potential wiring line 9B. 3) In the second area B, the first comb-shaped electrodes connected to the reference potential include a first comb-shaped electrode connected to the first reference-potential wiring line 9A and a first comb-shaped electrode connected to the second reference-potential wiring line 9B. 4) In the second area B, all of the second comb-shaped electrodes connected to the reference potential are connected to the second reference-potential wiring line 9B.

The longitudinally coupled resonator acoustic wave filter 3, which includes the configurations 1) to 4) described above, in the receive filter 1A defining and functioning as an acoustic wave filter achieves an increase of the out-of-band attenuation of the receive filter 1A. Thus, the duplexer 10 achieves improved isolation characteristics. The details of this will be described below with the details of the circuit configuration in the present example embodiment.

As illustrated in FIG. 1, the receive filter 1A includes the longitudinally coupled resonator acoustic wave filter 3, the acoustic wave resonators, the first signal terminal 4A, the second signal terminal 4B, an inductor L1, and an inductor L2. The longitudinally coupled resonator acoustic wave filter 3 is connected between the first signal terminal 4A and the second signal terminal 4B. A signal received from the common connection terminal 2 is input to the first signal terminal 4A, and is output through devices in the receive filter 1A from the second signal terminal 4B.

Specifically, the acoustic wave resonators in the receive filter 1A include multiple serial arm resonators and multiple parallel arm resonators. More specifically, the serial arm resonators in the receive filter 1A include a serial arm resonator S1, a serial arm resonator S2, and a serial arm resonator S3. The serial arm resonator S1 is connected between the first signal terminal 4A and the longitudinally coupled resonator acoustic wave filter 3. The serial arm resonator S2 and the serial arm resonator S3 are connected in series to each other between the longitudinally coupled resonator acoustic wave filter 3 and the second signal terminal 4B.

More specifically, the parallel arm resonators in the receive filter 1A include a parallel arm resonator P1 and a parallel arm resonator P2. The parallel arm resonator P1 is connected between the reference potential and the connection point between the serial arm resonator S1 and the longitudinally coupled resonator acoustic wave filter 3. The parallel arm resonator P2 is connected between the reference potential and the connection point between the serial arm resonator S2 and the serial arm resonator S3. The parallel arm resonator P1 is connected to the first reference-potential terminal 12A. The first reference-potential terminal 12A is connected to the inductor L1. In contrast, the parallel arm resonator P2 is connected to the second reference-potential terminal 12B. The second reference-potential terminal 12B is connected to the inductor L2. The inductor L1 and the inductor L2 are connected to the reference potential.

The parallel arm resonator P1 is connected to the first reference-potential wiring line 9A. The first reference-potential wiring line 9A is connected to the inductor L1 through the first reference-potential terminal 12A. Thus, among all of the IDT electrodes in the longitudinally coupled resonator acoustic wave filter 3, comb-shaped electrodes of some of the IDT electrodes and the parallel arm resonator P1 are connected in common to the reference potential through the inductor L1.

In contrast, the parallel arm resonator P2 is connected to the second reference-potential wiring line 9B. The second reference-potential wiring line 9B is connected to the inductor L2 through the second reference-potential terminal 12B. Thus, among all of the IDT electrodes in the longitudinally coupled resonator acoustic wave filter 3, comb-shaped electrodes of some of the IDT electrodes and the parallel arm resonator P2 are connected in common to the reference potential through the inductor L2.

However, the circuit configuration of the receive filter 1A, which is an acoustic wave filter according to an example embodiment of the present invention is not limited to that described above. For example, the inductor L1 and the inductor L2 are not necessarily provided. An acoustic wave filter according to an example embodiment of the present invention may have any configuration as long as it includes the longitudinally coupled resonator acoustic wave filter 3, the first reference-potential wiring line 9A, and the second reference-potential wiring line 9B.

The transmit filter 1B includes the serial arm resonators, the parallel arm resonators, the third signal terminal 4C, the fourth signal terminal 4D, an inductor L3, and an inductor L4.

More specifically, the serial arm resonators of the transmit filter 1B include a serial arm resonator S11a, a serial arm resonator S11b, a serial arm resonator S12a, a serial arm resonator S12b, a serial arm resonator S13, and a serial arm resonator S14. The serial arm resonators are connected in series to each other between the third signal terminal 4C and the fourth signal terminal 4D. More specifically, in the circuit configuration, the serial arm resonator S11a, the serial arm resonator S11b, the serial arm resonator S12a, the serial arm resonator S12b, the serial arm resonator S13, and the serial arm resonator S14 are provided in this order from the third signal terminal 4C side.

More specifically, the parallel arm resonators of the transmit filter 1B include a parallel arm resonator P11, a parallel arm resonator P12, a parallel arm resonator P13, and a parallel arm resonator P14. The parallel arm resonator P11 is connected between the third signal terminal 4C and the reference potential. The parallel arm resonator P12 is connected between the reference potential and the connection point between the serial arm resonator S11b and the serial arm resonator S12a. The parallel arm resonator P13 is connected between the reference potential and the connection point between the serial arm resonator S12b and the serial arm resonator S13. The parallel arm resonator P14 is connected between the reference potential and the connection point between the serial arm resonator S13 and the serial arm resonator S14.

The parallel arm resonator P11, the parallel arm resonator P12, and the parallel arm resonator P13 are connected in common to the inductor L3. The parallel arm resonator P14 is connected to the inductor L4. The inductor L3 and the inductor L4 are connected to the reference potential. However, the circuit configuration of the transmit filter 1B is not limited to that described above.

As described above, the duplexer 10 according to the present example embodiment achieves improved isolation characteristics. The details of the advantageous effects will be described below by comparing the present example embodiment with a first comparison example and a second comparison example.

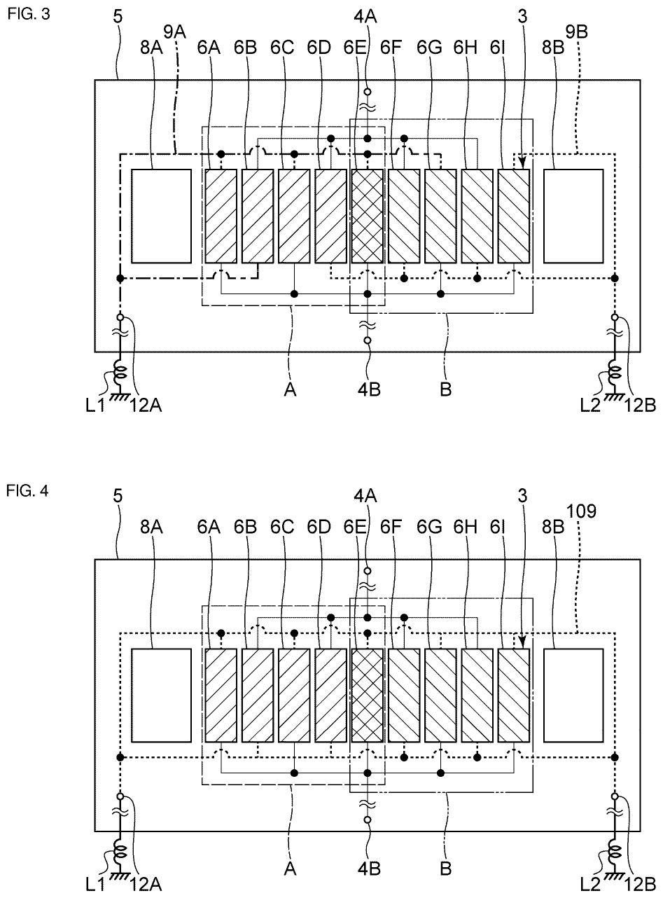

The circuit configurations of the first comparison example and the second comparison example are different from that according to the first example embodiment only in the receive filter's configuration of wiring lines connecting the longitudinally coupled resonator acoustic wave filter and the parallel arm resonators to the reference potential. As illustrated in FIG. 4, a receive filter according to the first comparison example includes a reference-potential wiring line 109. The reference-potential wiring line 109 is connected to the reference potential. The reference-potential wiring line 109 is connected to all of the comb-shaped electrodes connected to the reference potential.

The reference-potential wiring line 109 is connected to both of the parallel arm resonator P1 and the parallel arm resonator P2 which are illustrated in FIG. 1. As illustrated in FIG. 4, the reference-potential wiring line 109 is connected to the reference potential through both of the inductor L1 and the inductor L2.

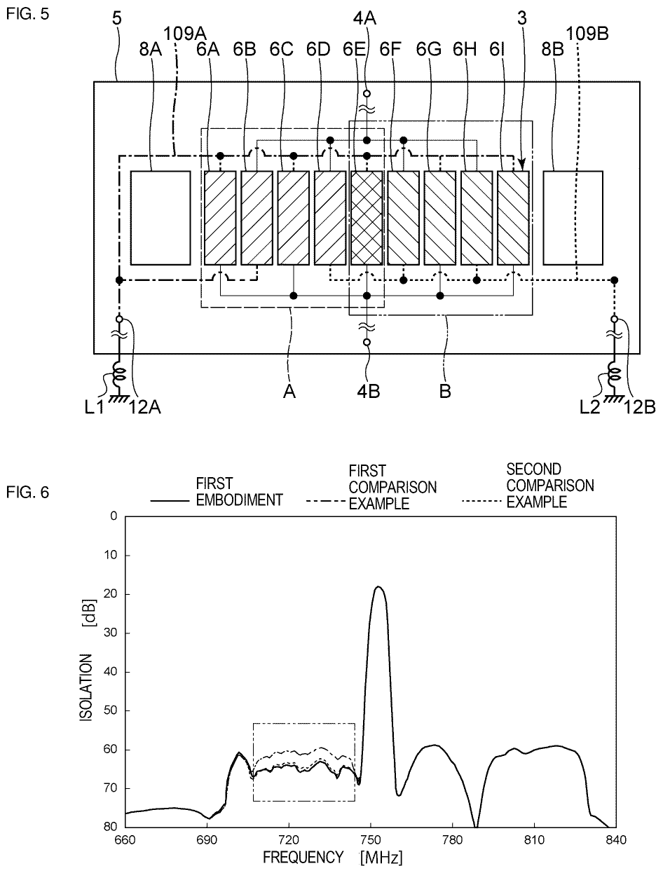

As illustrated in FIG. 5, a receive filter according to the second comparison example includes a first reference-potential wiring line 109A and a second reference-potential wiring line 109B. The first reference-potential wiring line 109A and the second reference-potential wiring line 109B are connected to the reference potential. The first reference-potential wiring line 109A is connected to the reference potential through the inductor L1. The second reference-potential wiring line 109B is connected to the reference potential through the inductor L2.

All of the first comb-shaped electrodes connected to the reference potential are connected to the first reference-potential wiring line 109A. The second comb-shaped electrodes connected to the reference potential include a second comb-shaped electrode connected to the first reference-potential wiring line 109A and a second comb-shaped electrode connected to the second reference-potential wiring line 109B. Specifically, the second comb-shaped electrode of the IDT electrode 6B is connected to the first reference-potential wiring line 109A. The second comb-shaped electrodes of the IDT electrode 6D, the IDT electrode 6F, and the IDT electrode 6H are connected to the second reference-potential wiring line 109B.

The first reference-potential wiring line 109A illustrated in FIG. 5 is connected to the parallel arm resonator P1 illustrated in FIG. 1. The second reference-potential wiring line 109B illustrated in FIG. 5 is connected to the parallel arm resonator P2 illustrated in FIG. 1.

The isolation characteristics are compared among the first example embodiment, the first comparison example, and the second comparison example. In the first example embodiment, the first comparison example, and the second comparison example, the passband of the transmit filters is about 703 MHz to about 748 MHz, and the passband of the receive filters is about 758 MHz to about 803 MHz, for example.

FIG. 6 is a diagram illustrating isolation characteristics of duplexers according to the first example embodiment, the first comparison example, and the second comparison example.

In FIG. 6, as illustrated by using a surrounding long dashed double-short dashed line, it was discovered that the first example embodiment achieves more improved isolation characteristics than those in the first comparison example and the second comparison example.

Specifically, in the first comparison example, the minimum of the absolute value of isolation is about 59.5, which is small, in the passband of the transmit filter. In the second comparison example, the minimum of the absolute value of isolation is about 62.3 in the passband of the transmit filter. The second comparison example achieves more improved isolation characteristics than those in the first comparison example. In contrast, in the first example embodiment, the minimum of the absolute value of isolation is about 63.1, which is large, in the passband of the transmit filter. That is, the first example embodiment achieves further improved isolation characteristics than the second comparison example.

The attenuation-frequency characteristics of the transmit filter 1B and the receive filter 1A in the first example embodiment will be described below. The attenuation-frequency characteristics of the transmit filter and the receive filter according to the second comparison example will be also described below.

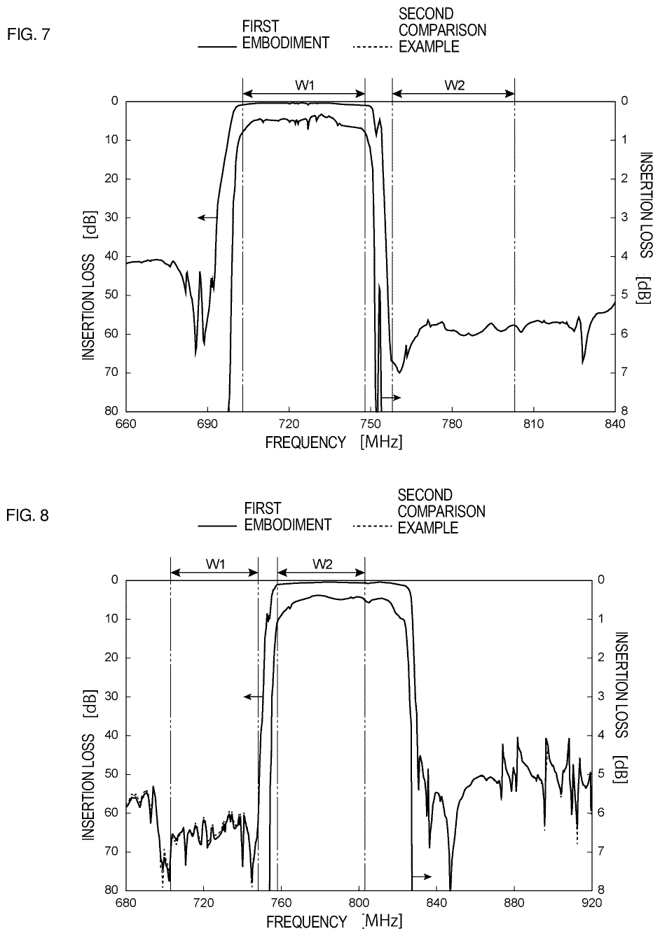

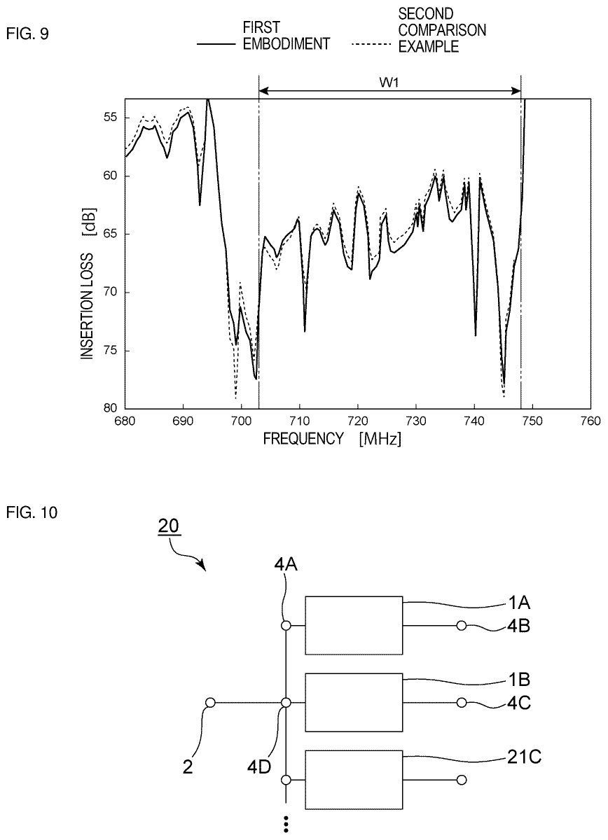

FIG. 7 is a diagram illustrating attenuation-frequency characteristics of the transmit filters according to the first example embodiment and the second comparison example. FIG. 8 is a diagram illustrating attenuation-frequency characteristics of the receive filters according to the first example embodiment and the second comparison example. FIG. 9 is an enlarged view of the vicinity of the passband of the transmit filters in FIG. 8. In FIGS. 7 to 9, the passband of the transmit filters is represented by W1. In FIGS. 7 and 8, the passband of the receive filters is represented by W2.

As illustrated in FIG. 7, there is very little difference in the attenuation-frequency characteristics of the transmit filters between the first example embodiment and the second comparison example.

As illustrated in FIGS. 8 and 9, in the first example embodiment, the out-of-band attenuation of the receive filter is larger than that in the second comparison example. More specifically, in the passband W1, the attenuation of the receive filter according to the first example embodiment is larger than that according to the second comparison example. Thus, the duplexer 10 according to the first example embodiment may achieve improved isolation characteristics.

In the first example embodiment, an example in which only one filter device in the multiplexer is an acoustic wave filter according to an example embodiment of the present invention is described. However, multiple filter devices in a multiplexer may be acoustic wave filters according to example embodiments of the present invention.

Preferably, at least one filter device in a multiplexer is an acoustic wave filter according to an example embodiment of the present invention, and the passband of the at least one acoustic wave filter is positioned in a higher range than the passband of at least one filter device other than the acoustic wave filter. This may more reliably improve the isolation characteristics of the multiplexer. The state in which a first one of the passbands is positioned on a higher range than a second one of the passbands means that all of the frequencies in the first one of the passbands are higher than all of the frequencies in the second one of the passbands.

As in the first example embodiment illustrated in FIG. 1, it is preferable that multiple parallel arm resonators include the parallel arm resonator P1 connected to the first reference-potential wiring line 9A and the parallel arm resonator P2 connected to the second reference-potential wiring line 9B. This makes it possible that the frequency at the attenuation pole contributed by the parallel arm resonator P1 is different from that contributed by the parallel arm resonator P2. This may achieve a wide range of choices with respect to the frequency range in a band having a large out-of-band attenuation and with respect to adjustment of the magnitude of attenuation in the band.

More specifically, in the receive filter 1A defining and functioning as an acoustic wave filter, the path on which the first reference-potential wiring line 9A is connected to the reference potential is different from the path on which the second reference-potential wiring line 9B is connected to the reference potential. Therefore, the path on which the parallel arm resonator P1 is connected to the reference potential is different from the path on which the parallel arm resonator P2 is connected to the reference potential. This causes a state in which, in the attenuation-frequency characteristics of the acoustic wave filter, the frequency at the attenuation pole contributed by the parallel arm resonator P1 is different from that contributed by the parallel arm resonator P2.

In the present example embodiment, the piezoelectric substrate 5 illustrated in FIG. 3 is mounted in a package substrate (not illustrated) as a chip including the terminals, the wiring lines, and the resonators. The inductor L1, the inductor L2, the inductor L3, and the inductor L4 illustrated in FIG. 1 are provided in the package substrate. As described above, on the piezoelectric substrate 5, the first reference-potential wiring line 9A is not connected to the second reference-potential wiring line 9B. Similarly, on the piezoelectric substrate 5, the first reference-potential terminal 12A is not connected to the second reference-potential terminal 12B. However, the package substrate may include a common path on which the receive filter 1A defining and functioning as an acoustic wave filter is connected to the reference potential.

For example, the inductor L1 may be provided on the piezoelectric substrate 5. In this case, for example, the first reference-potential wiring line 9A is connected to the inductor L1. The inductor L1 is connected to the first reference-potential terminal 12A. That is, the first reference-potential wiring line 9A is connected to the first reference-potential terminal 12A through the inductor L1. The first reference-potential wiring line 9A is connected to the reference potential through the inductor L1 and the first reference-potential terminal 12A.

Similarly, for example, the inductor L2 may be provided on the piezoelectric substrate 5. In this case, for example, the second reference-potential wiring line 9B is connected to the inductor L2. The inductor L2 is connected to the second reference-potential terminal 12B. That is, the second reference-potential wiring line 9B is connected to the second reference-potential terminal 12B through the inductor L2. The second reference-potential wiring line 9B is connected to the reference potential through the inductor L2 and the second reference-potential terminal 12B.

FIG. 10 is a schematic view of a multiplexer according to a second example embodiment of the present invention.

A multiplexer 20 according to the present example embodiment includes three or more filter devices. Specifically, the multiplexer 20 includes the receive filter 1A, the transmit filter 1B, a filter device 21C, and at least one different filter device. The receive filter 1A and the transmit filter 1B are, for example, the same or substantially the same as those according to the first example embodiment.

For example, the filter device 21C may be a receive filter, or may be a transmit filter. The same is true for the filter device other than the receive filter 1A, the transmit filter 1B, and the filter device 21C.

The multiplexer 20 includes the receive filter 1A defining and functioning as an acoustic wave filter according to an example embodiment of the present invention. As in the first example embodiment, the multiplexer 20 achieves improved isolation characteristics.

The multiplexer 20 may include an acoustic wave filter an example embodiment of the present invention and which is other than the receive filter 1A. In this case, for example, the passband of the acoustic wave filter is preferably positioned on a higher range than the passband of the filter device 21C or the like. This may more reliably improve isolation characteristics.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter comprising:
a longitudinally coupled resonator acoustic wave filter including n IDT electrodes, where n is an odd number of seven or more; and
a first reference-potential wiring line and a second reference-potential wiring line each connected to a reference potential; wherein
the longitudinally coupled resonator acoustic wave filter includes a first area and a second area, the first area including a first-end-positioned IDT electrode to a center-positioned IDT electrode in a direction in which the n IDT electrodes are arranged side by side, the second area including the center-positioned IDT electrode to a second-end-positioned IDT electrode in the direction in which the n IDT electrodes are arranged side by side;
each of the IDT electrodes includes a first comb-shaped electrode and a second comb-shaped electrode interdigitated with each other, one of the first comb-shaped electrode and the second comb-shaped electrode in each of the IDT electrodes being connected to a signal potential, an other electrode of the first comb-shaped electrode and the second comb-shaped electrode being connected to the reference potential, a first one in each pair of adjacent IDT electrodes including the first comb-shaped electrode connected to the signal potential, a second one in the pair including the first comb-shaped electrode connected to the reference potential;
in the first area, all of the first comb-shaped electrodes connected to the reference potential are connected to the first reference-potential wiring line, and the second comb-shaped electrodes connected to the reference potential include the second comb-shaped electrode connected to the first reference-potential wiring line and the second comb-shaped electrode connected to the second reference-potential wiring line; and
in the second area, the first comb-shaped electrodes connected to the reference potential include the first comb-shaped electrode connected to the first reference-potential wiring line and the first comb-shaped electrode connected to the second reference-potential wiring line, and all of the second comb-shaped electrodes connected to the reference potential are connected to the second reference-potential wiring line.

2. The acoustic wave filter according to claim 1, further comprising:
a piezoelectric substrate including the longitudinally coupled resonator acoustic wave filter; and
a first reference-potential terminal and a second reference-potential terminal on the piezoelectric substrate; wherein
the first reference-potential wiring line is connected to the reference potential through the first reference-potential terminal; and
the second reference-potential wiring line is connected to the reference potential through the second reference-potential terminal.

3. The acoustic wave filter according to claim 1, further comprising:
a plurality of parallel arm resonators including a parallel arm resonator connected to the first reference-potential wiring line and a parallel arm resonator connected to the second reference-potential wiring line.

4. The acoustic wave filter according to claim 2, wherein the piezoelectric substrate includes only piezoelectric material.

5. The acoustic wave filter according to claim 4, wherein the piezoelectric material includes lithium tantalate, lithium niobate, zinc oxide, aluminum nitride, crystal, or lead zirconate titanate.

6. The acoustic wave filter according to claim 1, wherein the n IDT electrodes include nine IDT electrodes.

7. The acoustic wave filter according to claim 1, wherein the longitudinally coupled resonator acoustic wave filter includes a pair of reflectors on opposite sides of the n IDT electrodes in an acoustic-wave propagation direction.

8. A multiplexer comprising:
a plurality of filter devices; wherein at least one of the plurality of filter devices includes the acoustic wave filter according to claim 1.

9. The multiplexer according to claim 8, wherein the at least one of the plurality of filter devices has a passband in a higher range than a passband of at least another one of the plurality of filter devices.

10. The multiplexer according to claim 8, wherein the plurality of filter devices include at least three filter devices.

11. The multiplexer according to claim 8, wherein the plurality of filter devices include two filter devices.

12. The multiplexer according to claim 8, further comprising:
a piezoelectric substrate including the longitudinally coupled resonator acoustic wave filter; and
a first reference-potential terminal and a second reference-potential terminal on the piezoelectric substrate; wherein
the first reference-potential wiring line is connected to the reference potential through the first reference-potential terminal; and
the second reference-potential wiring line is connected to the reference potential through the second reference-potential terminal.

13. The multiplexer according to claim 8, further comprising:
a plurality of parallel arm resonators; wherein
the plurality of parallel arm resonators include a parallel arm resonator connected to the first reference-potential wiring line and a parallel arm resonator connected to the second reference-potential wiring line.

14. The multiplexer according to claim 10, wherein the piezoelectric substrate includes only piezoelectric material.

15. The multiplexer according to claim 14, wherein the piezoelectric material includes lithium tantalate, lithium niobate, zinc oxide, aluminum nitride, crystal, or lead zirconate titanate.

16. The multiplexer according to claim 8, wherein the n IDT electrodes include nine IDT electrodes.

17. The multiplexer according to claim 8, wherein the longitudinally coupled resonator acoustic wave filter includes a pair of reflectors on opposite sides of the n IDT electrodes in an acoustic-wave propagation direction.
